(19) United States
(12) Patent Application Publication
(10) Pub. No.: US 2025/0180597 A1
(43) Pub. Date: Jun. 5, 2025

(54) MEMS INERTIAL SENSOR WITH HIGH RESISTANCE TO STICTION

(71) Applicant: STMicroelectronics S.r.l., Agrate Brianza (IT)

(72) Inventors: Gabriele GATTERE, Castronno (IT); Francesco RIZZINI, Passirano (IT); Alessandro TOCCHIO, Milano (IT)

(73) Assignee: STMicroelectronics S.r.l., Agrate Brianza (IT)

(21) Appl. No.: 18/913,878

(22) Filed: Oct. 11, 2024

Related U.S. Application Data
(63) Continuation of application No. 18/147,629, filed on Dec. 28, 2022, now Pat. No. 12,117,464.
Application No. 18/147,629 is a continuation of application No. 16/898,350, filed on Jun. 10, 2020, now Pat. No. 11,543,428.

(30) Foreign Application Priority Data
Jun. 20, 2019 (IT) 102019000009651

(51) Int. Cl. G01P 15/125; B81C 1/00; G01P 15/08

(52) U.S. Cl. CPC G01P 15/125; B81C 1/00968; G01P 2015/0874

(57) ABSTRACT

An inertial structure is elastically coupled through a first elastic structure to a supporting structure so as to move along a sensing axis as a function of a quantity to be detected. The inertial structure includes first and second inertial masses which are elastically coupled together by a second elastic structure to enable movement of the second inertial mass along the sensing axis. The first elastic structure has a lower elastic constant than the second elastic structure so that, in presence of the quantity to be detected, the inertial structure moves in a sensing direction until the first inertial mass stops against a stop structure and the second elastic mass can move further in the sensing direction. Once the quantity to be detected ends, the second inertial mass moves in a direction opposite to the sensing direction and detaches the first inertial mass from the stop structure.

### BACKGROUND

### Technical Field

The present disclosure relates to a MEMS (MicroElectroMechanical System) inertial sensor with high resistance to stiction. In particular, hereinafter reference is made to a MEMS accelerometer of a capacitive type.

### Description of the Related Art

As is known, MEMS accelerometers comprise a suspended inertial mass having a main extension plane. Generally, the inertial mass is carried to be mobile in a direction (sensing axis) lying in or parallel to the main extension plane, as a result of external accelerations.

For instance, FIGS. 1A and 1B show a known MEMS accelerometer 1 of a capacitive type in two different operating positions. In particular, the MEMS accelerometer 1 extends in a first plane XY of a Cartesian reference system XYZ and has a sensing axis S extending in the same first plane XY, in particular parallel to a first Cartesian axis Y of the Cartesian reference system XYZ. In detail, FIG. 1A shows the MEMS accelerometer 1 in a rest condition. In this condition, the centroid O of the MEMS accelerometer 1 is set in a point do along the first Cartesian axis Y.

The MEMS accelerometer 1 comprises an inertial mass 3, of semiconductor material (for example, silicon), having a mass m and extending on a substrate which is not visible in FIGS. 1A and 1B. Here, the inertial mass 3 has the shape, in top view, of a quadrangular (for example, rectangular) frame and has an opening 9.

A first and a second electrode 13, 15, of conductive material (for example, silicon), extend in the opening 9 and are anchored to the substrate (not visible) by respective anchoring portions 13A, 15A. In particular, the electrodes 13, 15 have, in top view, an elongated quadrangular shape (for example, rectangular) with main extension along a second Cartesian axis X of the Cartesian reference system XYZ.

The inertial mass 3 has a first and a second inner surface 3A, 3B, facing the opening 9 and the electrodes 13, 15 and extending perpendicular to the sensing axis S, here parallel to a second plane XZ of the Cartesian reference system XYZ.

In greater detail, in the rest condition of the MEMS accelerometer 1, the first and second inner surfaces 3A, 3B are arranged at a first and a second distance d₁, d₂ from the first and, respectively, the second electrode 13, 15. The first and second surfaces 3A, 3B and the respective first and second electrodes 13, 15 are capacitively coupled to each other and form the plates of corresponding capacitors, having capacitances C₁, C₂ in the rest condition of the MEMS accelerometer 1.

The inertial mass 3 is here passed throughout its entire thickness (in a direction parallel to a third Cartesian axis Z) by a plurality of holes 17 that allow, during the manufacturing process, the release of the inertial mass 3.

The inertial mass 3 is coupled to a constraint element 5, fixed to and rigid with the substrate (not illustrated), by a spring element 7 configured to allow a displacement, here a translation, of the inertial mass 3 along the sensing axis S in response to an external acceleration aₑₓₜ having a component directed parallel to the first Cartesian axis Y. In the illustrated embodiment, the constraint element 5 is arranged on the outside of the inertial mass 3 and coupled to a first outer wall 3C of the frame shape of the latter.

The MEMS accelerometer 1 further comprises a stop element 19, for example formed by a fixed region extending from the substrate (not shown) at a distance from the inertial mass 3. In particular, in the illustrated embodiment, the stop element 19 is arranged on the outside of the inertial mass 3, on a second outer wall 3D of the latter, opposite to the first outer wall 3C. In the rest condition of the MEMS accelerometer 1, illustrated in FIG. 1A, the stop element 19 is arranged at a stop distance dₛ from the second outer wall 3D of the inertial mass 3.

In use, the inertial mass 3 and the electrodes 13, 15 are biased at respective biasing voltages, which result, for example, in an effective voltage of approximately 1 V between the inertial mass 3 and the electrodes 13, 15.

As a result of the biasing, the inertial mass 3 is subjected to a total electrostatic force Fₑₗ, given by the sum of a first and a second electrostatic force Fₑₗ₁, Fₑₗ₂. In detail, the first electrostatic force Fₑₗ₁ acts between the first electrode 13 and the first inner surface 3A, and the second electrostatic force Fₑₗ₂ acts between the second electrode 15 and the second inner surface 3B.

The MEMS accelerometer 1 is designed so that, in the rest condition (FIG. 1A), the first and second distances d₁, d₂ between the inertial mass 3 and the electrodes 13, are equal to each other, as are the first and second capacitances C₁, C₂; therefore, the first and second electrostatic forces Fₑₗ₁, Fₑₗ₂ are equal to each other and the total electrostatic force Fₑₗ is zero.

Consequently, in rest condition, the spring element 7 is undeformed.

In use, an external acceleration aₑₓₜ, acting on the fixed structure of the MEMS accelerometer 1 and directed along the sensing axis S (for example, downwards in the drawing plane), causes a translation of the inertial mass 3 along the sensing axis S in an opposite direction to the external acceleration aₑₓₜ, as shown in FIG. 1B.

Consequently, the distances d₁, d₂ (and therefore the capacitances C₁, C₂) vary. In particular, with the illustrated external acceleration aₑₓₜ, the first distance d₁ decreases and the second distance d₂ increases; moreover, since it is known that the capacitances C₁, C₂ are inversely proportional to the respective distances d₁, d₂, the first capacitance C₁ increases and the second capacitance C₂ decreases.

The translation of the inertial mass 3 is interrupted when it abuts against the stop element 19, having covered a distance equal to the stop distance dₛ (FIG. 1B). In this situation, the centroid O of the inertial mass 3 is in a translated position d_{T}=d₀+dₛ along the first Cartesian axis Y. Moreover, the distance between the first electrode 13 and the first inner surface 3A decreases and becomes equal to d₁-dₛ and the distance between the second electrode 15 and the second inner surface 3B increases and becomes equal to d₂+dₛ. Consequently, the first and second capacitances C₁, C₂, as well as the respective first and second electrostatic forces Fₑₗ₁, Fₑₗ₂, are no longer equal.

In particular, when in abutment, the inertial mass 3 is subject to a total electrostatic force Fₑₗ, given by Eq. 1:

$${F}_{el} = {F}_{el 1} + {F}_{el 2} = \frac{1}{2} \frac{ε {A}_{el}}{{( {d}_{1} - {d}_{s} )}^{2}} {ΔV}^{2} + \frac{1}{2} \frac{ε {A}_{el}}{{( {d}_{2} + {d}_{s} )}^{2}} {ΔV}^{2} \qquad ( 1 )$$

where ε is the dielectric constant, Aₑₗ is the area of the electrodes 13, 15 (and therefore of the portion of the surfaces 3A, 3B of the inertial mass 3 facing them), and ΔV is the voltage between the plates of the capacitors C₁, C₂.

Moreover, when the inertial mass 3 abuts against the stop element 19 (FIG. 1B), a stiction force Fₐ acts thereon and tends to keep it into abutment, because the inertial mass 3 and the stop element 19 are of the same material (for example, silicon). As soon as the external acceleration aₑₓₜ terminates (i.e., aₑₓₜ=0), an elastic return force Fₘ exerted by the spring element 7 brings the inertial mass 3 back into the rest position illustrated in FIG. 1A. In particular, the elastic return force Fₘ acts along the sensing axis S, opposite to the displacement direction of the inertial mass 3.

The elastic return force Fₘ is given in a known way by the following equation:

$${F}_{m} = - k \cdot {d}_{s} \qquad ( 2 )$$

To overcome the stiction force Fₐ and bring the inertial mass 3 back into the rest position (FIG. 1A), so that it can detect further accelerations acting from the outside, the spring element 7 is designed so that the elastic return force Fₘ compensate both the stiction force Fₐ and the total electrostatic force Fₑₗ set up in the step of FIG. 1B. In other words, it is desired that:

$${F}_{m} > α ( {F}_{el} + {F}_{a ( t = 0 )} ) \qquad ( 3 )$$

where F_{a (t=0)} is the native stiction force (i.e., the stiction force estimated prior to first use of the MEMS accelerometer 1) and α is a safety coefficient.

However, estimation and compensation of the stiction force Fₐ are complex.

In fact, the stiction force Fₐ depends upon a large number of tribological aspects linked to the geometry, materials, manufacturing processes, and operating conditions and is moreover variable in time.

In addition, the safety coefficient α in Eq. 3 cannot be freely set and derives from trade-off considerations between the desired performance and the manufacturing costs. In fact, it depends upon constructional and electromechanical parameters of the MEMS accelerometer 1 (e.g., the constant k of the spring element 7, the stop distance dₛ between the second outer wall 3D of the inertial mass 3 and the stop element 19 and the area Aₑₗ of the electrodes 13, 15). However, current constructional requirements (such as bandwidth, packaging, noise and full scale) do not allow the aforesaid constructional parameters to be freely chosen, and thus it is not always possible to maximize the safety coefficient α.

### BRIEF SUMMARY

One of more embodiments of the present disclosure provide a MEMS inertial sensor that overcomes one or more of the drawbacks of the prior art.

According to the present disclosure a MEMS inertial sensor is provided.

### BRIEF DESCRIPTION OF THE SEVERAL VIEWS OF THE DRAWINGS

For a better understanding of the present disclosure, embodiments thereof are now described, purely by way of non-limiting example, with reference to the attached drawings, wherein:

FIGS. 1A and 1B schematically show a known MEMS inertial sensor in top view respectively in a rest position and in presence of an external acceleration;

FIG. 2 schematically show the present inertial MEMS sensor in top view and in a rest position;

FIGS. 3-5 schematically show the present MEMS inertial sensor according to an embodiment in successive positions, when subject to an external acceleration;

FIG. 6 shows a possible implementation of the present MEMS inertial sensor;

FIG. 7 shows a general block diagram of an electronic apparatus incorporating a MEMS inertial sensor;

FIG. 8 is a schematic illustration of the present MEMS inertial sensor in top view according to another embodiment; and

FIG. 9 is a schematic illustration of the present MEMS inertial sensor in top view according to a further embodiment.

### DETAILED DESCRIPTION

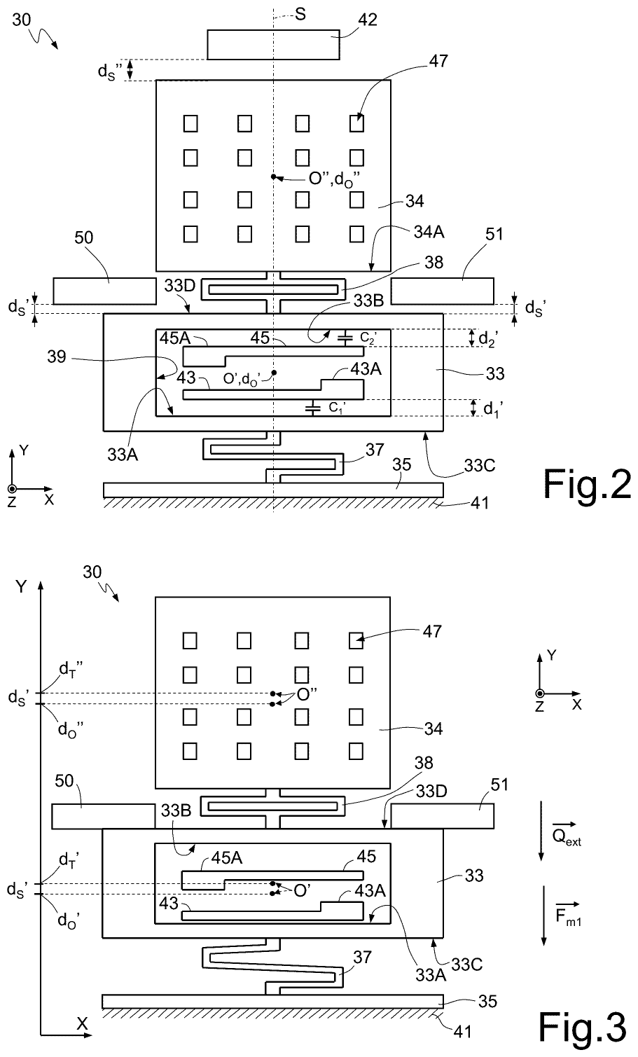

FIG. 2 shows a MEMS inertial sensor, in particular a MEMS accelerometer 30 of a capacitive type configured to detect external accelerations directed along a sensing axis S, extending in a first plane XY of a Cartesian reference system XYZ, in particular parallel to a first Cartesian axis Y of the Cartesian reference system XYZ. In particular, FIG. 2 shows the MEMS accelerometer 30 in a rest condition.

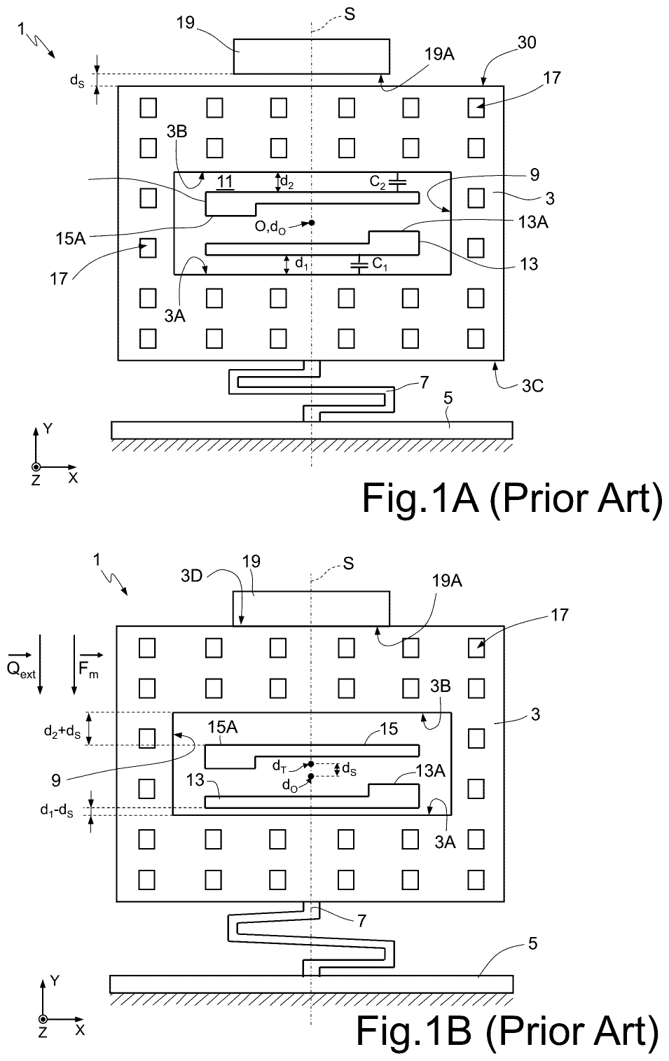

The MEMS accelerometer 30 comprises a first and a second inertial mass 33, 34, of semiconductor material (for example, silicon), having a first and, respectively, a second mass m₁, m₂. In general, for a same sensitivity and behavior of the MEMS accelerometer 30, as explained in detail hereinafter, the sum of the first and second masses m₁, m₂ is equal to the mass m of the MEMS accelerometer 1 of FIGS. 1A-1B, and the second mass m₂ is, for example, greater than the first mass m₁. For instance, the ratio between the first and second masses m₁/m₂ is advantageously 0.5.

The first and second inertial masses 33, 34 have a substantially planar structure with main dimensions along the first Cartesian axis Y and a second Cartesian axis X of the Cartesian reference system XYZ and a thickness (along a third Cartesian axis Z) negligible with respect to the first two dimensions. They therefore mainly extend in the first plane XY.

The first and second inertial masses 33, 34 have respective centroids O′ and O″ that, in the rest condition of FIG. 2, are arranged in a first and, respectively, a second rest position d₀′, d₀″ (it is noted that the notation d₀′, d₀″, etc., will be used hereinafter to indicate both the positions of the centroids O′ and O″ and their distances from the center of the Cartesian system XYZ along the first Cartesian axis Y).

The first and second masses 33, 34 extend above the substrate, not visible in FIG. 2 and part of a fixed structure 41 of semiconductor material (for example, silicon).

In the illustrated embodiment, the first inertial mass 33 has the shape, in top view, of a quadrangular (for example, rectangular) frame and has an opening 39. A first and a second electrode 43, 45, of conductive material (for example, doped silicon), extend within the opening 39 starting from the substrate (not illustrated) to which they are anchored by respective anchoring portions 43A, 45A.

In particular, the electrodes 43, 45 have, in top view, an elongated quadrangular shape (for example, rectangular) with main extension along the second Cartesian axis X.

The first inertial mass 33 has a first and a second inner surface 33A, 33B, facing the opening 39 and the electrodes 43, 45, respectively, and extending perpendicular to the sensing axis S, here parallel to a second plane XZ of the Cartesian reference system XYZ.

In the rest condition of the MEMS accelerometer 30 of FIG. 2, the first and second electrodes 43, 45 are arranged at a first and, respectively, a second distance d₁′, d₂′ from the respective first and second surface 33A, 33B. Moreover, the first and second surfaces 33A, 33B are capacitively coupled to the first and, respectively, to the second electrode 43, 45 and form the plates of corresponding capacitors having a first and, respectively, a second capacitance C₁′, C₂′.

The first inertial mass 33 is coupled to a fixed constraint element 35, fixed to and rigid with the substrate (not illustrated), through a first spring element 37 configured to allow a displacement, here a translation, of the first inertial mass 33 along the sensing axis S in response to an external acceleration aₑₓₜ having a component parallel to the first Cartesian axis Y. In the illustrated embodiment, the constraint element 35 is arranged outside of the first inertial mass 33 and is coupled to a first outer wall 33C of the frame shape of the latter by the first spring element 37. Moreover, the first spring element 37 is, for example, of the folded type with a serpentine shape in top view and has a first elastic constant k₁ typically of the same value as the elastic constant k of the spring element 7 of the MEMS accelerometer 1 of FIGS. 1A-1B, so as not to modify the sensitivity of the accelerometer 30. For instance, the first elastic constant k₁ may be comprised between 1 and 50 N/m.

The second inertial mass 34 is coupled to the first inertial mass 33 by a second spring element 38, having, for example, a substantially annular shape in top view. In particular, the second spring element 38 has a second elastic constant k₂ much greater than the first elastic constant k₁; for example, the ratio is equal to 0.01. Consequently, the second spring element 38 is stiffer than the first spring element 37.

The second spring element 38 is configured to deform, in presence of an external acceleration aₑₓₜ acting on the MEMS accelerometer 30 and directed along the sensing axis S, as described in detail hereinafter.

In FIG. 2, the second inertial mass 34 is further traversed, throughout its entire thickness, by a plurality of holes 47 that allow, during the manufacturing process, the release of the second inertial mass 34, in a per se known manner. Likewise, similar through holes can extend throughout the first inertial mass 33.

The MEMS accelerometer 30 further comprises a stop structure, here formed by a first and a second stop element 50, 51, for example of semiconductor material such as silicon, and formed by fixed regions, rigid with the fixed structure 41 and, for example, extending from the substrate (not shown) at a distance from the first inertial mass 33. In particular, in the illustrated embodiment, the stop elements 50, 51 are arranged between the first and second inertial masses 33, 34, facing a second outer wall 33D thereof, arranged on a side of the first inertial mass 33 opposite to the side of the first outer wall 33C. Moreover, in the embodiment illustrated in FIG. 2, the first and second stop elements 50, 51 face respective peripheral portions of the second outer wall 33D of the first inertial mass 33 and, in the rest condition of the first inertial mass 33, are arranged at a same first stop distance dₛ′ from the second outer wall 33D of the first inertial mass 33.

The MEMS accelerometer 30 further comprises a third stop element 42, arranged at a respective second stop distance dₛ″ from the second inertial mass 34 when the latter is in the rest condition (FIG. 2). In particular, the second stop distance dₛ″ is greater than the first stop distance dₛ′ and preferably greater than the maximum translation movement of the second inertial mass 34 during the statistically expected operation of the MEMS accelerometer 30, as clarified hereinafter.

In use, the first inertial mass 33 and the electrodes 43, 45 are biased at respective biasing voltages, which result, for example, in an effective voltage of approximately 1 V between the first inertial mass 33 and the electrodes 43, 45. As a result of the biasing, the first inertial mass 33 is subjected to a total electrostatic force Fₑₗ′, given by the sum of a first and of a second electrostatic force Fₑₗ₁′, Fₑₗ₂′. In detail, the first electrostatic force Fₑₗ₁′ acts between the first electrode 43 and the first surface 33A, and the second electrostatic force Fₑₗ₂′ acts between the second electrode 45 and the second surface 33B.

The MEMS accelerometer 30 is designed so that, in the rest condition (FIG. 2), the first and second distances d₁′, d₂′, as well as the first and second capacitances C₁′, C₂′, are equal to each other. Consequently, the first and second electrostatic forces Fₑₗ₁′, Fₑₗ₂′ are equal to each other and the total electrostatic force Fₑₗ′ is zero.

When the fixed structure 41 of the MEMS accelerometer 30 is subject to an external acceleration aₑₓₜ directed along the sensing axis S (for example, downwards in the drawing plane), the first and second inertial masses 33, 34 displace in the opposite direction (for example, upwards in the drawing plane), causing the extension of the first spring element 37.

In this step, the second inertial mass 34 and the second spring element 38 rigidly translate with the first inertial mass 33; in fact, due to the greater stiffness of the second spring element 38 as compared to the first spring element 37, the second spring element 38 remains substantially undeformed in the first part of the movement of the MEMS accelerometer 30.

Consequently, and analogously to what described with reference to FIG. 1B, the distances d₁′, d₂′ between the first inertial mass 33 and the electrodes 43, 45 (and therefore the capacitances C₁′, C₂′) vary. In the considered example, the first distance d₁′ decreases, and the second distance d₂′ increases; therefore, in this step, the first capacitance C₁′ increases, and the second capacitance C₂′ decreases.

The extension of the spring element 37 and the translation of the first inertial mass 33 are interrupted when the first inertial mass 33 abuts against the stop elements 50, 51, i.e., when the first inertial mass 33 has covered a distance equal to the first stop distance dₛ′. This condition is represented in FIG. 3, which shows, along the first Cartesian axis Y, both the rest positions d₀′, d₀″ of the centroids O′ and O″ of the first and second inertial masses 33, 34 and the positions d_{T}′ and d_{T}″ of the same centroids O′ and O″ when the first inertial mass 33 stops against the stop elements 50, 51.

In particular, in this condition, d_{T}′ constitutes a first translated position of the first inertial mass 33, with d_{T}′=d₀′+dₛ′. Consequently, the distance between the first electrode 43 and the first inner surface 33A is equal to d₁′−dₛ′, and the distance between the second electrode 45 and the second inner surface 33B is equal to d₂′+dₛ′; therefore, the first and second capacitances C₁′, C₂′, as well as the respective first and second electrostatic forces Fₑₗ₁′, Fₑₗ₂′, are no longer equal to each other.

Consequently, the first inertial mass 33 is subject to a total electrostatic force Fₑₗ′ defined according to Eq. (1) analogously to the total electrostatic force Fₑₗ of the MEMS accelerometer 1 of FIGS. 1A-1B.

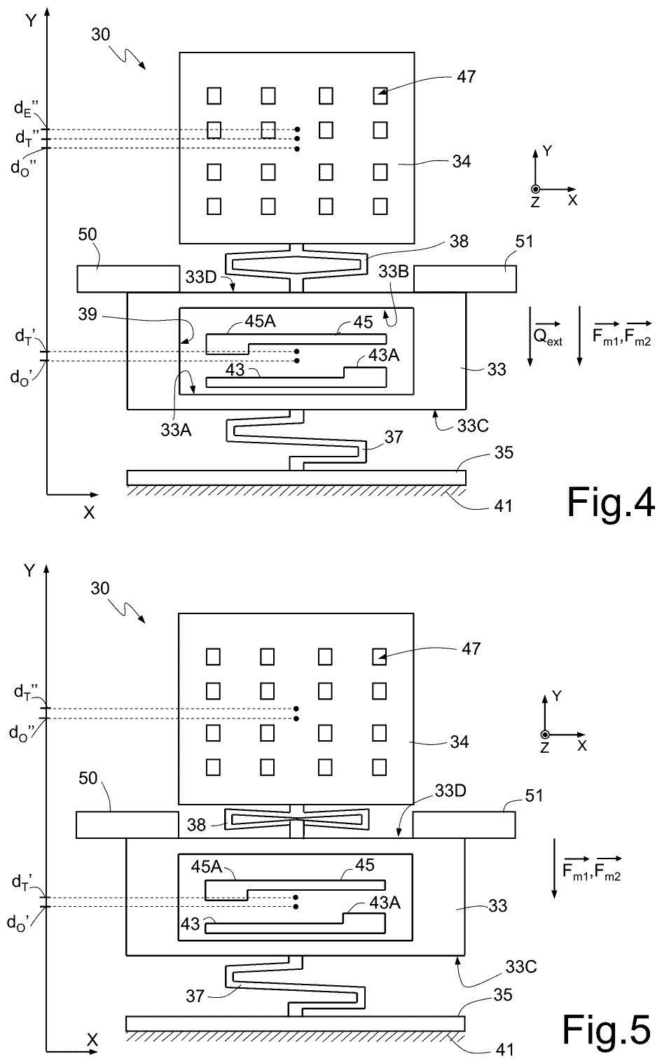

Next, FIG. 4, since the external acceleration aₑₓₜ still acts on the MEMS accelerometer 30, the first inertial mass 33 abuts against the stop elements 50, 51 and the second inertial mass 34 is free to move. The latter proceeds with its movement, and the second spring element 38 extends until the structure formed by the first and second inertial masses 33, 34 reaches an equilibrium, depending upon the geometrical parameters (position of the third stop element 42, stiffness of the second spring element 38) and upon the amplitude of the external acceleration aₑₓₜ, generally coming to a stop before the third stop element 42. At equilibrium, the centroid O″ of the second inertial mass 34 moves into a final translated position at a distance d_{E}″=d_{T}″+dₓ″ from the center of the Cartesian system XYZ, where dₓ″ is the distance covered by the second inertial mass 34 after the first inertial mass 33 has come into abutment against the stop elements 50, 51.

When the external acceleration aₑₓₜ terminates (i.e., aₑₓₜ=0), the return forces of the first and second spring elements 37, 38 act to bring the first and second inertial masses 33, 34 back into the respective rest positions d₀′, d₀″ of FIG. 2. In particular, the spring elements 37, 38 are subject to respective elastic return forces Fₘ₁, Fₘ₂ acting along the sensing axis S, opposite to the previous extension direction (for example, downwards in the drawing plane).

With the MEMS accelerometer 30 of FIGS. 2-4, if the first inertial mass 33 is subject to a stiction force Fₐ′ such as to keep it in contact with the respective stop elements 50, 51, the second mass 34 (which is not into abutment against the third stop element 42) acts so as to detach it from the stop elements 50, 51. In fact, the second inertial mass 34 and the second spring element 38 form a dynamic system with one degree of freedom subject to an acceleration step and, when the external acceleration aₑₓₜ becomes zero, the second inertial mass 34 is recalled towards its initial equilibrium position, as a result of the elastic potential energy stored in the second spring element 38 (FIG. 5).

The return movement of the second spring element 38 and therefore of the second inertial mass 34 exerts a thrust “backwards” (downwards in the drawing plane) upon the first inertial mass 33, which adds to the elastic return force Fₘ₁ of the first spring element 37 so as to overcome the total electrostatic force Fₑₗ′ and possible stiction forces Fₐ′ acting on the first inertial mass 33, detaching it from the stop elements 50, 51. The MEMS accelerometer 30 can thus return into the initial rest position of FIG. 2.

A processing system (not illustrated), coupled to the electrodes 43, 45 and to the first inertial mass 33 is thus able to detect the variations of the capacitances C₁′, C₂′ and calculate the value of the external acceleration aₑₓₜ therefrom (in the limits of the full-scale value of the MEMS accelerometer 30), analogously to known MEMS accelerometers.

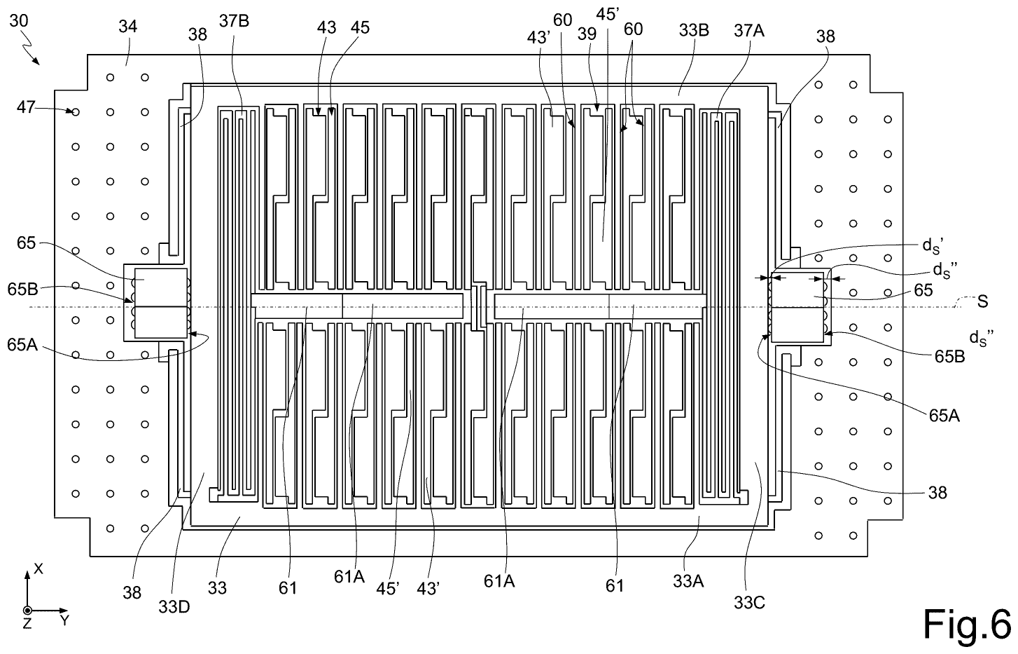

FIG. 6 shows an implementation of the present MEMS accelerometer. In detail, parts similar to the ones illustrated and described with reference to FIGS. 2-5 are designated in FIG. 6 by the same reference numbers.

In particular, the first inertial mass 33 still has the shape of a rectangular frame, with two major sides 33A, 33B and two minor sides 33C and 33D. Intermediate arms 60 extend from the two major sides 33A, 33B towards the center of the opening 39 and are arranged perpendicular to the sensing axis S (therefore, parallel to the second Cartesian axis X).

The electrodes 43, 45 of FIG. 2 are here formed by a plurality of regions (hereinafter referred to as first electrode regions 43′ and second electrode regions 45′) arranged parallel to each other, in pairs. In particular, each pair of regions, formed by a first electrode region 43′ and a second electrode region 45′, is arranged between two adjacent intermediate arms 60.

In the illustrated embodiment, the intermediate arms 60 have a length that is slightly shorter than one half of the width (in a direction parallel to the second Cartesian axis X) of the opening 39. A pair of first springs 37A, 37B forms the first spring element 37 of FIG. 2; the first springs 37A, 37B extend from respective minor sides 33C, 33D of the first inertial mass 33 towards the inside of the opening 39 and are connected to transverse arms 61, also extending inside the opening 39 in a central position and in a direction parallel to displacement direction S (thus parallel to the first Cartesian axis Y). The transverse arms 61 are provided with respective anchoring portions 61A, rigid with the fixed structure (not illustrated).

Moreover, in the MEMS accelerometer 30 of FIG. 6, the second inertial mass 34 also has the shape of a frame and surrounds the first inertial mass 33. Here, the second spring element 38 of FIG. 2 is formed by four second springs, designated once again by 38, with linear shape, extending from the corners of the frame shape of the first inertial mass 33.

A pair of stop elements 65 extends between the first and second inertial masses 33, 34. In particular, each stop element 65 has a first face 65A facing the first inertial mass 33 and arranged (in the rest condition of the MEMS accelerometer 30) at the first stop distance dₛ′ from the latter, and a second face 65B facing the second inertial mass 34 and arranged (in the rest condition of the MEMS accelerometer 30) at the second stop distance dₛ″ therefrom. As may be noted, the first stop distance dₛ′ between the first inertial mass 33 and the first face 65A is smaller than the second stop distance dₛ″ between the second inertial mass 34 and the second face 65B so that, irrespective of the displacement direction S (to the right or to the left in the drawing of FIG. 6), first the first inertial mass 33 abuts against the first face 65A of one of the two stop elements 65 and only later the second inertial mass 34 abuts against the second face 65B of the other stop element 65.

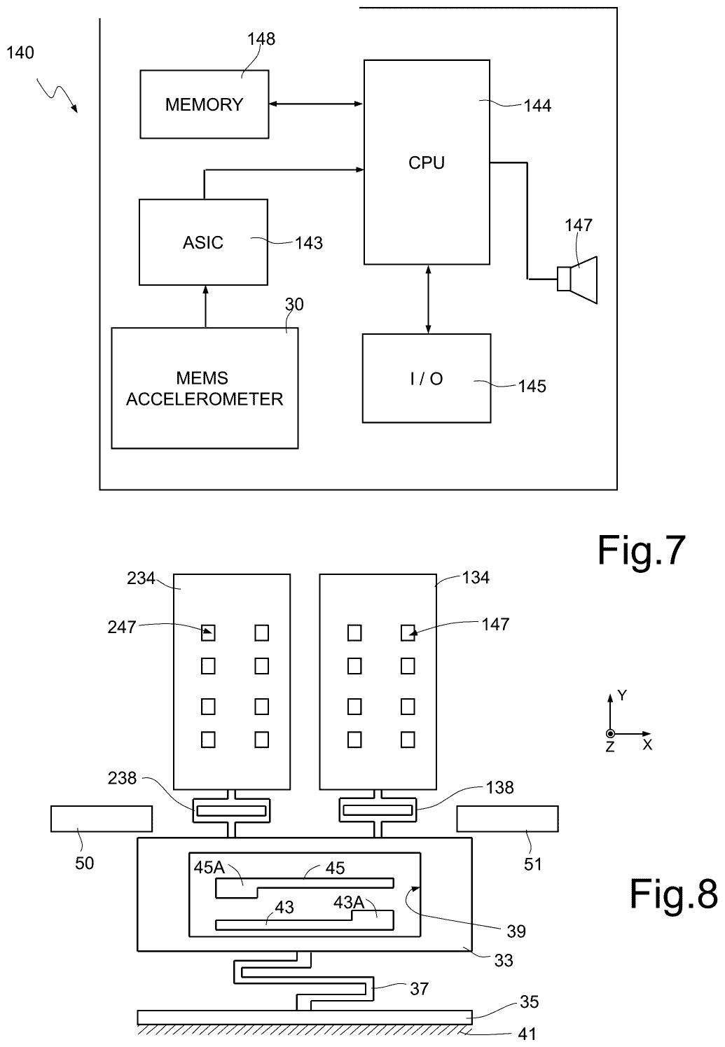

FIG. 7 shows an electronic apparatus 140 comprising the MEMS accelerometer 30 of FIGS. 2-6.

The MEMS accelerometer 30 is connected to an ASIC 143 which provides the corresponding read interface. The ASIC 143 can be formed in the same die as the MEMS accelerometer 30. In further embodiments, the ASIC 143 is formed in a separate die and accommodated in the same package as the MEMS accelerometer 30.

The electronic apparatus 140 is, for example, a portable mobile-communication apparatus, such as a mobile phone, a PDA (Personal Digital Assistant), a portable computer, a digital audio player with voice-recording capacity, a photographic video camera, or a controller for videogames; in detail, the electronic apparatus 140 is generally able to process, store, and/or transmit and receive signals and information.

The electronic apparatus 140 further comprises a microprocessor 144, receiving the acceleration signals detected by the MEMS accelerometer 30, and an input/output interface 145, for example provided with a keypad and a display, connected to the microprocessor 144. Moreover, the electronic apparatus 140 here comprises a speaker 147, for generating sounds on an audio output (not illustrated), and an internal memory 148.

The present MEMS inertial sensor has various advantages.

In particular, any possible stiction of the first inertial mass 33 is overcome by virtue of the elastic thrust action exerted by the second inertial mass 34 during the return motion of the latter into the rest position, without substantially having to modify the main constructional and electromechanical parameters of the MEMS accelerometer 30 that determine the performance thereof. In this way, the accelerometer 30 has a sensitivity, resonance frequency, linearity, and accuracy similar to those obtainable by a similar known accelerometer with the same weight, preventing failure due to the stiction of the first inertial mass 33 to the stop elements 50, 51.

In addition, the full scale of the second inertial mass 34 can be defined independently from the full scale of the first inertial mass 33; consequently, it is possible to set the full scale of the second inertial mass 34 so that it is sufficiently large to prevent contact of the second inertial mass 34 with the third stop element 42 for the majority of shock profiles to which the second inertial mass 34 may statistically be subjected in the service life of the MEMS accelerometer 30.

Finally, it is clear that modifications and variations may be made to the MEMS inertial sensor described and illustrated herein, without thereby departing from the scope of the present disclosure.

For instance, the present inertial sensor may be of a different type, such as a gyroscope, an inclinometer, or a vibrometer.

Furthermore, the second inertial mass 34 can have a mass m₂ smaller than the mass m₁ of the first inertial mass 33.

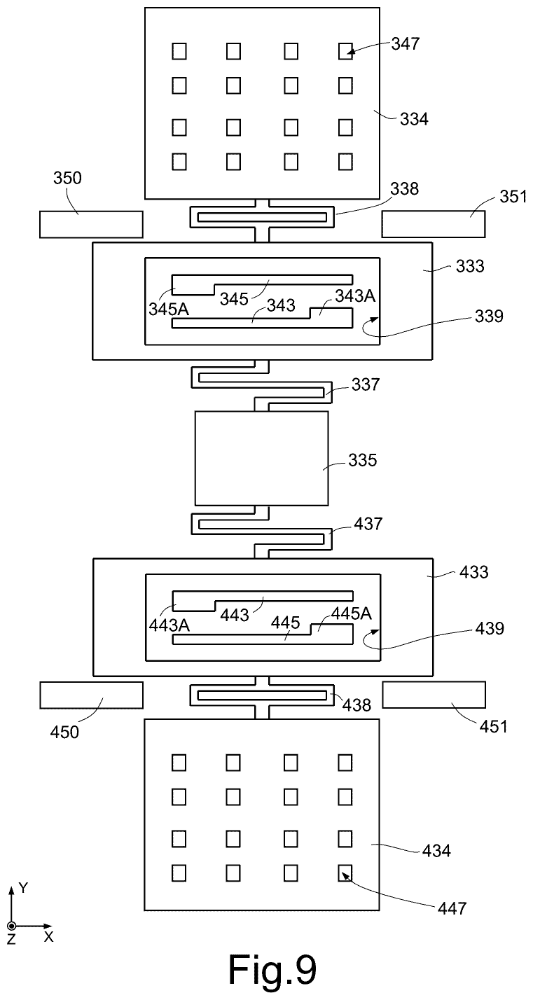

In addition, as shown in FIGS. 8 and 9, the first and second inertial masses 33, 34 can be divided into a respective plurality of submasses connected via a respective plurality of elastic elements.

In further detail, FIG. 8 shows a MEMS accelerometer 130 having a general structure similar to that of the MEMS accelerometer 30 illustrated in FIGS. 2-5, so that parts similar to the ones illustrated and described with reference to FIGS. 2-5 are designated in FIG. 8 by the same reference numbers and will not be described any further.

In particular, the MEMS accelerometer 130 comprises a first and a second submass 134, 234, having a general structure similar to the second inertial mass 34 of FIGS. 2-5 and masses, the sum of which is equal to the second mass m₂ of the second inertial mass 34 of FIGS. 2-5.

Moreover, the MEMS accelerometer 130 comprises a third and a fourth elastic element 138, 238 that elastically couple the first and, respectively, the second submass 134, 234 to the first inertial mass 33. The third and fourth elastic elements 138, 238 have a structure similar to the second elastic element 38 of FIGS. 2-5 and elastic constants the sum of which is equal to the second elastic constant k₂ of the second elastic element 38.

In use, the MEMS accelerometer 130 operates similarly to the MEMS accelerometer 30 of FIGS. 2-5.

FIG. 9 shows a MEMS accelerometer 330 having a general structure similar to the MEMS accelerometer 30 of FIGS. 2-5, where the first and second inertial masses 33, 34 are divided into respective first and second submasses 333, 433, 334, 434, which have a general structure similar to the first and, respectively, the second inertial mass 34 of FIGS. 2-5. The MEMS accelerometer 330 further comprises first and second further stop elements 350, 351, 450, 451, having a general structure similar to the first and second stop elements 50, 51 of FIGS. 2-5 and interposed between the first submasses 333, 334 of the first and second inertial masses 33, 34 and, respectively, the second submasses 433, 434 of the first and second inertial masses 33, 34.

The first and second submasses 333, 433 of the first inertial mass 33 have masses the sum whereof is equal to the first mass m₁ of the first inertial mass 33 of FIGS. 2-5 and that are constrained to the constraint element 335 by elastic elements 337, 437, having elastic constants the sum of which is equal to the first elastic constant k₁ of the first elastic element 37 of FIGS. 2-5.

The first and second submasses 334, 434 of the second inertial mass 34 have a general structure similar to the first and, respectively, second submasses 134, 234 of the second inertial mass 34 of FIG. 8 and are connected to the first submass 333 and, respectively, to the second submass 433 of the first inertial mass 33 by respective elastic elements 338, 438, having a general structure similar to the third and fourth elastic elements 138, 238 of FIG. 8.

In use, the MEMS accelerometer 330 operates similarly to the MEMS accelerometer 30 of FIGS. 2-5.

In addition, the number of submasses into which the first and second inertial masses 33, 34 can be divided may be greater than two.

Moreover, the various embodiments described may be combined so as to provide further solutions.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. (canceled)

2. A device, comprising:
a first mass;
a second mass;
a first stopper element aligned with a second stopper element along a first axis, the first stopper element having a first side that is opposite to a second side, the first stopper element being between a first part of the first mass and a first part of the second mass, and the first side of the first stopper element is configured to contact and stop the first part of the first mass along the first axis, the second side of the first stopper element is configured to contact and stop the first part of the second mass along the first axis; and
a first elastic element between a second part of the first mass and a second part of the second mass, and the first elastic element is configured to enable movement of the first mass along the first axis.

3. The device of claim 2, wherein the first stopper element includes a third side opposite a fourth side, the third side being transverse to the first side and the second side, the third side of the first stopper element configured to interact with a surface of the second part of the first mass, the surface being transverse to the first part of the first mass.

4. The device of claim 2, wherein the first side of the first stopper element including a first plurality of bumps and the second side of the first stopper element includes a second plurality of bumps.

5. The device of claim 2, wherein the second stopper element includes a first side that is opposite to a second side, the first side of the second stopper element being configured to contact and stop a third part of the first mass.

6. The device of claim 5, wherein the third part of the first mass is substantially parallel to the first part of the first mass.

7. The device of claim 2, wherein the first part of the first mass is substantially perpendicular to the second part of the first mass.

8. The device of claim 7, wherein the first part of the first mass is configured to interact with a plurality of bumps on the first side of the first stopper element.

9. The device of claim 8, wherein the plurality of bumps of the first stopper element are configured to stop movement of the first mass along the first axis.

10. The device of claim 2, wherein the first stopper element includes a third side and a fourth side that are each transverse to the first side and the second side, wherein the first stopper element includes at least one bump on at least two sides of the first, second, third, and fourth sides.

11. The device of claim 10, wherein in a resting condition the first side is spaced from the first part of the first mass by a first distance and the second side is spaced from the second part of the second mass by a second distance that is less than the first distance.

12. A device, comprising:
a first mass;
a plurality of electrodes within the first mass;
a second mass;
a first stopper structure being between the first mass and the second mass, the first stopper structure including one or more first bumps along a first side of the first stopper structure, the one or more first bumps being configured to interact with the first mass, and a first portion of the first mass being between the plurality of electrodes and the first stopper structure, and the first stopper structure spaced from the first mass by a first distance in a resting condition and the first stopper structure spaced from the second mass by a second distance in the resting condition, and the first distance being less than the second distance;
a second stopper structure spaced from the first stopper structure by the first mass, the second stopper structure including one or more second bumps along a second side of the second stopper structure, the one or more second bumps being configured to interact with a second portion of the first mass, the second portion of the first mass being between the plurality of electrodes and the second stopper structure.

13. The device of claim 12, wherein the second mass includes a first surface of a first portion that is perpendicular to a second surface of a second portion, the first surface and the second surface facing the first stopper structure.

14. The device of claim 12, further comprising:
a fixed constraint element;
a first spring element coupling the first mass to the fixed constraint element, the first spring element configured to enable a movement of the first mass along an axis a second spring element coupling the second mass to the first mass.

15. The device of claim 14, wherein:
the first spring element has a first elastic constant; and
the second spring element has a second elastic constant greater than the first elastic constant.

16. The device of claim 14, wherein:
the first mass is configured to move in a first direction along the axis to abut the one or more first bumps along the first side of the first stopper structure.

17. The device of claim 12, wherein the plurality of electrodes is completely surrounded by the first mass.

18. The device of claim 17, wherein the plurality of electrodes form a capacitor with the first mass.

19. A device, comprising:
a substrate;
a first mass having a first surface that is transverse to a second surface;
a second mass;
a first stopper structure fixed to the substrate, the first stopper structure has a first surface transverse to a second surface, the first surface of the first stopper structure faces the first surface of the first mass and the second surface of the first stopper structure faces the second surface of the first mass, the first stopper structure includes a third surface that is transverse to the first surface of the first stopper structure, the third surface of the first stopper structure faces and is configured to interact with the second mass.

20. The device of claim 19, wherein the first stopper structure further includes one or more first bumps at the first surface, and the one or more first bumps are configured to contact the first surface of the first mass.

21. The device of claim 20, comprising a second stopper structure that includes one or more second bumps.

22. The device of claim 19, further comprising:
a fixed constraint element fixedly coupled to the substrate.

23. The device of claim 19, further comprising an electrode, and the second mass completely surrounds the electrode.

24. A device, comprising:
a supporting structure;
an inertial structure suspended from the supporting structure, the inertial structure including:
a first inertial mass of semiconductor material, the first inertial mass including a first surface transverse to a second surface; and
a second inertial mass of semiconductor material;
a first spring element elastically coupling the inertial structure to the supporting structure, the first elastic structure is configured to enable a movement of the inertial structure along a sensing axis;
a second spring element;
a first stop element fixed to the supporting structure, the first stop element has a third surface transverse to a fourth surface, the third surface faces the first surface of the first inertial mass and the fourth surface faces the second surface of the first inertial mass, the first stop element includes a fifth surface that faces the second inertial mass, the first stop element is configured to limit a movement of the first inertial mass to a first distance; and
an electrode capacitively coupled to the second inertial mass, the electrode being completely surrounded by the second inertial mass.

25. The device of claim 24, further comprising a second stop element fixed to the supporting structure, the second stop element is spaced apart from the first stop element by the second inertial mass.
